(19) United States
(12) Patent Application Publication
(10) Pub. No.: US 2015/0261258 A1
(43) Pub. Date: Sep. 17, 2015

(54) DISPLAY DEVICE

(71) Applicant: Samsung Display Co., Ltd., Yongin-City (KR)

(72) Inventors: Hyun-Young KIM, Yongin-City (KR); Eun-Jae Na, Yongin-City (KR); Go-Eun Lee, Yongin-City (KR); Sang-Min Hong, Yongin-City (KR)

(21) Appl. No.: 14/463,958

(22) Filed: Aug. 20, 2014

(30) Foreign Application Priority Data
Mar. 17, 2014 (KR) 10-2014-0031160

(51) Int. Cl. G06F 1/16; G06F 3/041; H01L 51/50; H01L 27/32; H01L 29/786

(52) U.S. Cl. CPC G06F 1/1643; H01L 27/323; H01L 27/3248; H01L 29/7869; H01L 51/5056; H01L 51/5072; H01L 51/5092; H01L 51/5012; G06F 3/0412

(57) ABSTRACT

A display device is disclosed. In one aspect, the display device includes a display unit formed in the display area and an encapsulation substrate formed over the base substrate. The display device further includes a touch screen panel formed over the encapsulation substrate, a sealant film interposed between the base substrate and the encapsulation substrate, and a thermal conductor interposed between the sealant film and the encapsulation substrate.

### INCORPORATION BY REFERENCE TO ANY PRIORITY APPLICATIONS

This application claims priority to and the benefit of Korean Patent Application No. 10-2014-0031160, filed on Mar. 17, 2014, in the Korean Intellectual Property Office, the disclosure of which is incorporated herein in its entirety by reference.

### BACKGROUND

1. Field

The described technology generally relates to a display device.

2. Description of the Related Technology

Display devices, such as organic light-emitting diode (OLED) display devices include a thin film transistor (TFT) and are used as the displays of mobile devices such as smartphones, tablets, tablet personal computers (PCs), super-slim notebooks, digital cameras, camcorders, and personal digital assistants (PDAs), as well as other electronic/electrical products such as super-thin profile televisions.

In display devices, substrates enclosing a display unit are sealed to protect the display unit from the environment. A film of sealant is typically formed between the substrates and is hardened or melted to bond the substrates to each other. After sealing the substrates, the structural strength of the sealing portion should be maintained.

### SUMMARY OF CERTAIN INVENTIVE ASPECTS

One inventive aspect is a display device including a sealant with an improved structural strength to improve the reliability of the display device.

Another aspect is a display device including a substrate including a display area in which a display unit is formed and a non-display area extending outside the display area; an encapsulation portion which encapsulates the substrate; a touch screen panel formed on the encapsulation portion; and a sealing portion formed between the substrate and the encapsulation portion, wherein a thermal conduction portion is formed between the sealing portion and the encapsulation portion.

According to an embodiment, a wiring included in the touch screen panel is formed on a portion of an outer surface of the encapsulation portion that faces the non-display area in a vertical direction of the substrate, and the sealing portion extends from a portion of the encapsulation portion where the wiring is located to a portion of the encapsulation portion where the wiring is not located.

According to an embodiment, laser beams emitted by a laser apparatus are radiated to the sealing portion via the portion of the encapsulation portion where the wiring is not located.

According to an embodiment, energy emitted from the laser apparatus is transmitted to the thermal conduction portion via the sealing portion.

According to an embodiment, the non-display area includes a region in which a circuit pattern is formed.

According to an embodiment, the thermal conduction portion contacts the sealing portion.

According to an embodiment, a first surface of the thermal conduction portion contacts at least a portion of an upper surface of the sealing portion, and a second surface of the thermal conduction portion that is opposite to the first surface contacts the encapsulation portion.

According to an embodiment, the sealing portion is formed in a sealing area which is partially overlapped with the non-display area, around the display area, and the thermal conduction portion is formed in accordance with a trace of the sealing portion.

According to an embodiment, the thermal conduction portion includes a pattern having a plurality of openings.

According to an embodiment, the thermal conduction portion is a mesh-type pattern.

According to an embodiment, the thermal conduction portion includes metal.

According to an embodiment, a thermal conduction buffer layer is further formed between the encapsulation portion and the thermal conduction portion.

According to an embodiment, the thermal conduction buffer layer is at least partially overlapped with the thermal conduction portion.

According to an embodiment, at least a portion of a first surface of the thermal conduction buffer layer contacts the thermal conduction portion, and a second surface of the thermal conduction buffer layer that is opposite to the first surface contacts the encapsulation portion.

According to an embodiment, the thermal conduction buffer layer includes an inorganic material.

According to an embodiment, the touch screen panel is an on-cell touch screen panel integrally formed on the encapsulation portion, and the touch screen panel is an electrostatic capacitive type touch screen panel, a resistive type touch screen panel, an electro-magnetic type touch screen panel, a saw type touch screen panel, or an infrared type touch screen panel.

According to an embodiment, the sealing portion includes a glass frit.

Another aspect is a display device comprising a base substrate including a display area and a non-display area surrounding the display area; a display unit formed in the display area; an encapsulation substrate formed over the base substrate; a touch screen panel formed over the encapsulation substrate; a sealant film interposed between the base substrate and the encapsulation substrate; and a thermal conductor interposed between the sealant film and the encapsulation substrate.

According to an embodiment, the touch screen panel includes a wiring formed over the encapsulation substrate and facing the non-display area and the sealant film extends along the encapsulation substrate from a position overlapping the wiring to a position not overlapping the wiring. According to an embodiment, the thermal conductor is configured to receive thermal energy via the sealant film. According to an embodiment, the display device further comprises a circuit pattern formed in the non-display area. According to an embodiment, the thermal conductor contacts the sealant film. According to an embodiment, the thermal conductor has first and second surfaces opposing each other, wherein the first surface of the thermal conductor contacts at least a portion of an upper surface of the sealant film, and wherein the second surface of the thermal conductor contacts the encapsulation substrate.

According to an embodiment, the sealant film surrounds the display area and at least partially overlaps the non-display area and wherein the thermal conductor surrounds the display area and overlaps the sealant film. According to an embodiment, the thermal conductor defines a pattern having a plurality of openings. According to an embodiment, the thermal conductor defines a mesh-type pattern. According to an embodiment, the thermal conductor is formed at least partially of metal. According to an embodiment, the display device further comprises a thermal conduction buffer layer interposed between the encapsulation substrate and the thermal conductor. According to an embodiment, the thermal conduction buffer layer at least partially overlaps the thermal conductor. According to an embodiment, the thermal conduction buffer layer has first and second surfaces opposing each other, the first surface of the thermal conductor buffer layer contacts the thermal conductor, and the second surface of the thermal conduction buffer layer contacts the encapsulation substrate.

According to an embodiment, the thermal conduction buffer layer is formed at least partially of an inorganic material. According to an embodiment, the thickness of the thermal conduction buffer layer is less than that of the thermal conductor. According to an embodiment, the touch screen panel is integrally formed on the encapsulation substrate, and the touch screen panel is an electrostatic capacitive type touch screen panel, a resistive type touch screen panel, an electro-magnetic type touch screen panel, a saw type touch screen panel, or an infrared type touch screen pan. According to an embodiment, the touch screen panel comprises a plurality of electrode patterns formed on the encapsulation portion and at least one insulation layer electrically insulating the electrode patterns from each other.

According to an embodiment, the electrode patterns comprise a plurality of first electrode patterns and a plurality of second electrode patterns, the first electrode patterns are arranged in a first direction and are spaced apart from each other, and the second electrode patterns are arranged in a second direction that intersects the first direction and are spaced apart from each other. According to an embodiment, the display unit comprises a thin film transistor and an organic light-emitting diode (OLED) electrically connected to the thin film transistor and comprising an intermediate layer, wherein the intermediate layer includes a first electrode, a second electrode, and an emission layer interposed between the first and second electrodes. According to an embodiment, the sealant film comprises a glass frit.

### BRIEF DESCRIPTION OF THE DRAWINGS

FIG. 1 is an exploded perspective view of a display device according to an embodiment.

FIG. 2 is a perspective view of a touch screen panel included in the display device of FIG. 1.

FIG. 3 is a sectional view of a display panel included in the display device of FIG. 1.

FIG. 4 is a magnified sectional view of a portion of the display panel of FIG. 3 in which a sealing portion is formed.

FIG. 5 is a plan view of a sealing portion, a thermal conduction portion, and a thermal conduction buffer layer included in the display panel of FIG. 3.

### DETAILED DESCRIPTION OF CERTAIN INVENTIVE EMBODIMENTS

As the described technology allows for various changes and numerous embodiments, particular embodiments will be illustrated in the drawings and described in detail in the written description. However, this is not intended to limit the described technology to particular modes of practice and it is to be appreciated that all changes, equivalents, and substitutes that do not depart from the spirit and technical scope of the described technology are encompassed in the described technology. In the following description, a detailed description of disclosed technologies will not be provided if they are deemed to obscure the features of the described technology.

While such terms as “first,” “second,” etc., may be used to describe various components, such components must not be limited to the above terms. The above terms are used only to distinguish one component from another.

The terms used in the present specification are merely used to describe particular embodiments and are not intended to limit the described technology. Expressions used in the singular encompass the expression in the plural, unless the context clearly indicates otherwise. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

As used herein, the term “and/or” includes any and all combinations of one or more of the associated listed items. Expressions such as “at least one of,” when preceding a list of elements, modify the entire list of elements and do not modify the individual elements of the list.

A display device according to one or more embodiments will be described below in more detail with reference to the accompanying drawings. Those components that are the same or are in correspondence are given the same reference numeral throughout the figures and redundant explanations thereof may be omitted.

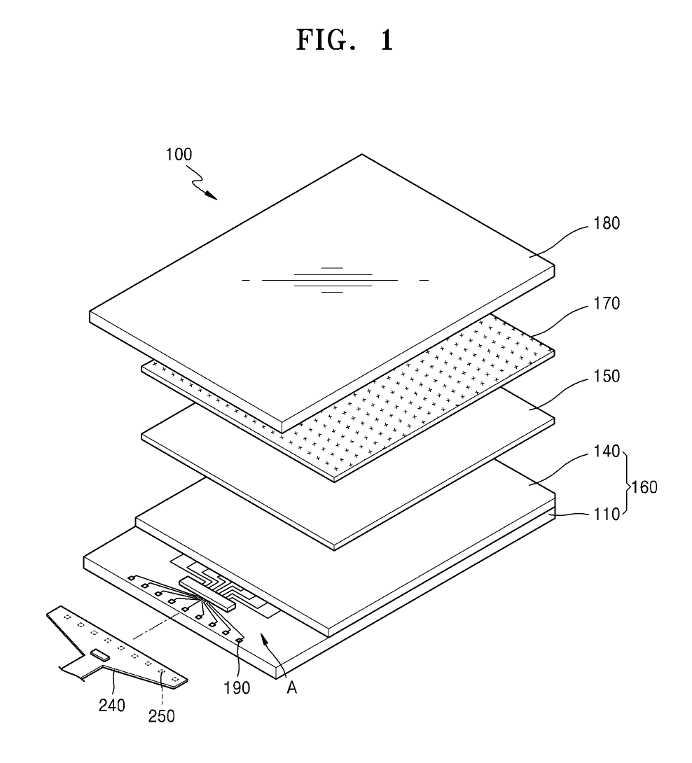

FIG. 1 is a perspective view of a display device 100 according to an embodiment.

The display device 100 illustrated in the embodiment of FIG. 1 is an organic light-emitting diode (OLED) display. However, the display device 100 is not limited thereto and may be any display device that displays images with applied power. For example, the display device may be a liquid crystal display (LCD), a field emission display (FED), or an electronic paper display (EPD).

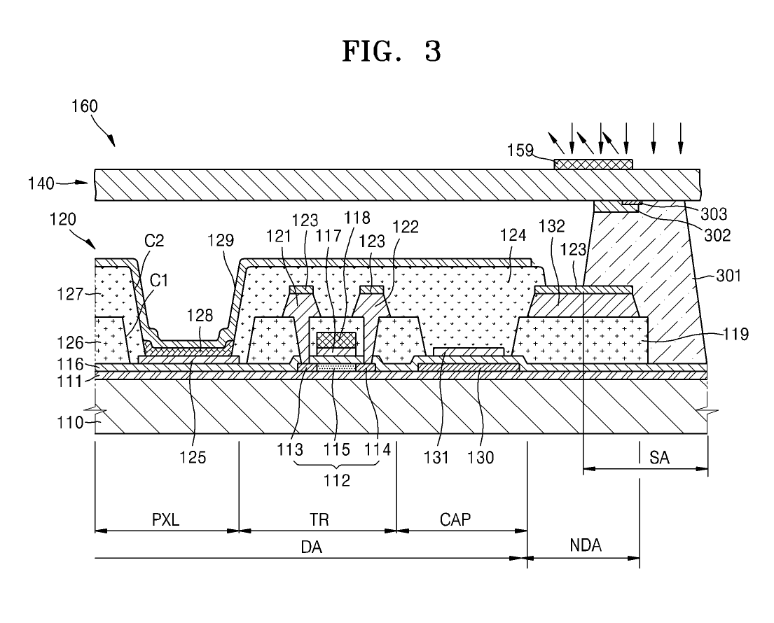

Referring to FIG. 1, the display device 100 includes a display panel 160, which includes a substrate or base substrate 110 and an encapsulation portion or encapsulation substrate 140 provided on the substrate 110. A display unit 120 (see FIG. 3), which displays images, is formed the substrate 110.

The substrate 110 may be a glass substrate having rigidity, a polymer resin substrate, a film substrate having flexibility, a metal substrate, or a combination thereof.

The encapsulation portion 140 may be a glass substrate, a polymer resin substrate, or a flexible film. The encapsulation portion 140 may be formed by alternately stacking an organic layer and an inorganic layer one or more times.

A sealing portion or sealant film 301 of FIG. 3 is formed between the substrate 110 and the encapsulation portion 140, in order to seal the display unit 120. The sealing portion 301 is formed along the edges opposing surfaces of the substrate 110 and the encapsulation portion 140. In some embodiments, the sealing portion includes a glass frit.

A touch screen panel 150 is formed on the encapsulation portion 140. The touch screen panel 150 may be an on-cell touch screen panel (TSP) including a touch screen pattern formed on the encapsulation portion 150. The touch screen panel 150 may be integrally formed on the encapsulation portion 140, but embodiments of the described technology are not limited thereto.

A polarization substrate 170 is formed on the touch screen panel 150. The polarization substrate 170 prevents external light from being reflected and emitted from the display unit 120.

A window cover 180 is provided on the polarization substrate 170 to protect the display device 100 from the environment. In some embodiments, the window cover 180 includes glass having rigidity.

An exposed area A extending from an edge of the encapsulation portion 140 is formed on the substrate 110. A plurality of pads 190 are arranged on the exposed area A of the substrate 110 in one direction so as to be spaced apart from one another.

Terminals 250 of a circuit board 240 are electrically connected to the pads 190 so that the pads 190 can receive a signal from an external source. The circuit board 240 may be a flexible printed circuit board (FPCB) having flexibility.

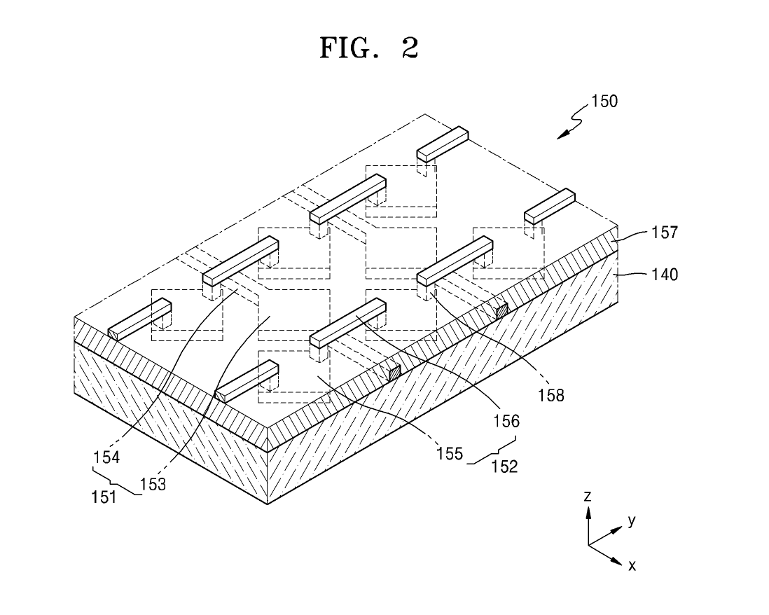

FIG. 2 illustrates the touch screen panel 150 of FIG. 1.

In the embodiment of FIG. 2, the touch screen panel 150 is an electrostatic capacitive type touch screen panel. However, the touch screen panel 150 is not limited thereto and may be a resistive type touch screen panel, an electro-magnetic type touch screen panel, a saw type touch screen panel, or an infrared type touch screen panel.

Referring to FIG. 1, the touch screen panel 150 is formed on the encapsulation portion 140 (also referred to as an encapsulation substrate). Although the touch screen panel 150 is integrally formed on the encapsulation substrate 140 in the FIG. 1 embodiment, the touch screen panel 150 may be formed on a separate substrate.

A plurality of first electrode pattern portions or first electrode patterns 151 and a plurality of second electrode pattern portions or second electrode patterns 152 are alternately arranged on the encapsulation substrate 140. The first electrode pattern portions 151 are aligned in a first direction (i.e., an X direction) of the encapsulation substrate 140 such that corners thereof face each other.

A second electrode pattern portion 152 is interposed between a pair of adjacent first electrode pattern portions 151. The second electrode pattern portions 152 are aligned in a second direction (i.e., a Y direction) of the encapsulation substrate 140 such that corners thereof face each other.

The first electrode pattern portions 151 include a plurality of first main body portions 153 and a plurality of first connection portions 154 electrically connecting the first main body portions 153 to each other.

The first main body portions 153 each have a diamond shape. The first main body portions 153 are aligned in the first direction (i.e., the X direction) of the encapsulation substrate 140. Each of the first connection portions 154 is formed between a pair of first main body portions 153 arranged adjacent to each other in the first direction (i.e., the X direction). Each of the first connection portions 154 connects a pair of first main body portions 153 to each other.

The second electrode pattern portions 152 include a plurality of second main body portions 155 and a plurality of second connection portions 156 electrically connecting the second main body portions 155 to each other.

The second main body portions 155 each have a diamond shape. The second main body portions 155 are aligned in the second direction (i.e., the Y direction) of the encapsulation substrate 140. Each of the second connection portions 156 connects a pair of second main body portions 155 to each other.

A pair of adjacent first main body portions 153 are connected to each other by a first connection portion 154 formed on the same plane as the first main body portions 153. A pair of second main body portions 155 adjacent to each other are connected to each other by a second connection portion 156 formed on a plane different from the plane where the first connection portion 154 are formed, in order to avoid interference between the second electrode pattern portions 152 and the first electrode pattern portions 151.

An insulation layer 157, covering both the first electrode pattern portions 151 and the second electrode pattern portions 152, may be formed on the encapsulation substrate 140. The insulation layer 157 insulates the first electrode pattern portions 151 from the second electrode pattern portions 152.

A plurality of contact holes 158 are formed in the insulation layer 157. The contact holes 158 are formed in regions of the insulation layer 157 that correspond to the corners of the second main body portions 155. The contact holes 158 are formed in regions of the insulation layer 157 in which the first electrode pattern portions 151 intersect with the second electrode pattern portions 152.

The second connection portions 156 are arranged across the insulation layer 157. Both ends of each second connection portion 156 each vertically extend to be buried in the contact holes 158. Both ends of each second connection portion 156 contact upper surfaces of adjacent second main body portions 155 corresponding to the second connection portion 156. Accordingly, each second connection portion 156 electrically connects a pair of adjacent second electrode pattern portions 152 to each other.

The first and second electrode pattern portions 151 and 152 are typically formed by photolithography. For example, the first and second electrode pattern portions 151 and 152 may be formed by patterning a transparent conductive layer formed by deposition, spin coating, sputtering, inkjet, or the like. The first and second electrode pattern portions 151 and 152 are formed of a transparent conductive layer, for example, a transparent material such as an indium tin oxide (ITO), an indium zinc oxide (IZO), a zinc oxide (ZnO), or an indium oxide (In₂O₃).

A protection layer (not shown) for covering the second connection portions 156 may be further formed on the insulation layer 157.

When an input unit, such as a finger, approaches or contacts the encapsulation substrate 140, the touch screen panel 150 measures electrostatic capacitance that changes between the first electrode pattern portions 151 and the second electrode pattern portions 152 and thus detects a touch location.

The display device 100 having this structure may perform the functions of a touch panel without increasing the thickness thereof. In addition, since the display device 100 uses an on-cell TSP in which the touch screen panel 150 is provided on an outer surface of the encapsulation substrate 140, the amount of reflection can be reduced even with strong external light. Thus, clear images may be achieved.

A thermal conduction portion or thermal conductor 302 of FIG. 3 providing a thermal conduction path for radiating a uniform laser beam on the sealing portion 301 is formed between the encapsulation portion 140 and the sealing portion 301.

This will now be described in detail below.

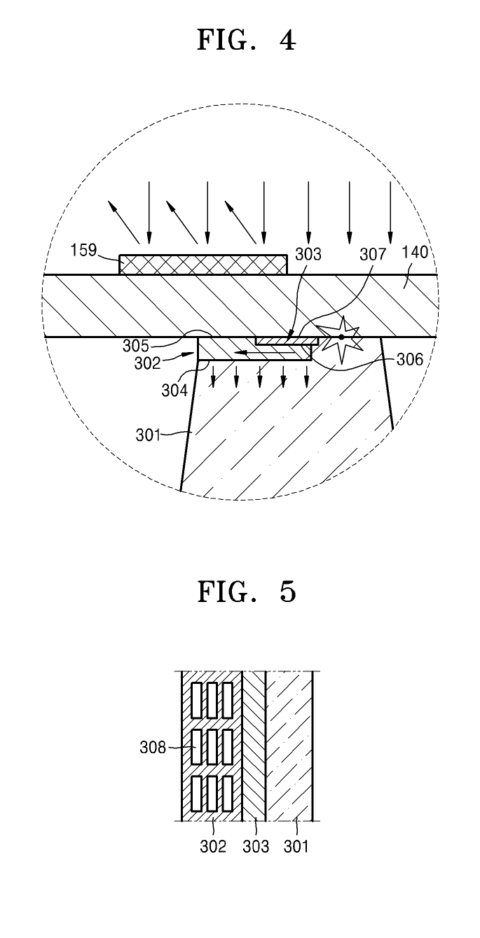

FIG. 3 is a sectional view of the display panel 160 of FIG. 1. FIG. 4 is a magnified sectional view of a portion of the display panel 160 of FIG. 3 in which the sealing portion 301 has been formed. FIG. 5 is a plan view of the sealing portion 301, the thermal conduction portion 302, and a thermal conduction buffer layer 303 of FIG. 3.

Referring to FIGS. 3 through 5, the substrate 110 includes a display area DA where the display unit 120 is formed, a non-display area NDA surrounding the display area DA, and a sealing area SA partially overlapping the non-display area NDA.

The display area DA includes a region PXL in which pixels are formed, a region TR in which transistors are formed, and a region CAP in which capacitors are formed. The non-display area NDA includes a region in which a circuit pattern electrically transceiving signals to or from the display area DA is formed. The sealing area SA includes a region in which the sealing portion 301 is formed.

The substrate 110 may be a glass substrate, a polymer substrate, a flexible film substrate, a metal substrate, or a combination thereof. The substrate 110 may be transparent, opaque, or semi-transparent.

A barrier layer 111 is formed on the substrate 110. The barrier layer 111 provides a flat surface over the substrate 110 and prevents contaminant elements from permeating through the substrate 110. The barrier layer 111 is formed by stacking organic layers, stacking inorganic layers, or alternately stacking organic and inorganic layers.

A semiconductor active layer 112 is formed on the barrier layer 111. The semiconductor active layer 112 may be formed of polycrystal silicon, but is not limited thereto, and may be formed of a semiconductor oxide.

For example, the oxide semiconductor may include an oxide of a material selected from the group of Group 4, 12, 13, and 14 metal elements, such as zinc (Zn), indium (In), gallium (Ga), stannum (Sn), cadmium (Cd), germanium (Ge), and hafnium (Hf), and a combination thereof.

The semiconductor active layer 112 includes a source region 113 and a drain region 114 which are formed by doping N-type impurity ions or P-type impurity ions therein. A channel region 115 undoped with impurities is formed between the source region 113 and the drain region 114.

A gate insulating layer 116 is formed to cover the semiconductor active layer 112. The gate insulation layer 116 is a single layer or a layer stack including an inorganic material such as a silicon oxide, a silicon nitride, or a metal oxide.

Gate electrodes 117 and 118 are formed on the gate insulating layer 116. The gate electrodes 117 and 118 are respectively a first layer 117 including a transparent conductive oxide and a second layer 118 including a metal. The first and second layers 117 and 118 are stacked on one another.

The first layer 117 includes at least one material selected from the group of an indium tin oxide (ITO), an indium zinc oxide (IZO), a zinc oxide (ZnO), an indium oxide (In₂O₃), an indium gallium oxide (IGO), and an aluminum zinc oxide (AZO).

The second layer 118 may be formed of at least one material selected from the group of aluminum (Al), platinum (Pt), palladium (Pd), silver (Ag), magnesium (Mg), gold (Au), nickel (Ni), neodymium (Nd), iridium (Jr), chromium (Cr), calcium (Ca), molybdenum (Mo), titanium (Ti), tungsten (W), and copper (Cu) in a single- or multi-layered structure.

An interlayer insulating layer 119 is formed to cover the stack of the gate electrodes 117 and 118. The interlayer insulation layer 119 includes an inorganic layer formed of a silicon oxide or a silicon nitride. The interlayer insulation layer 119 may include an organic layer.

A source electrode 121 and a drain electrode 122 are formed on the interlayer insulating layer 119. Contact holes are formed in the gate insulation layer 116 and the interlayer insulation layer 119 by selective etching in order to electrically connect the source electrode 121 to the source region 113 and the drain electrode 122 to the drain region 114.

The source electrode 121 and the drain electrode 122 may include the same material as the material used to form the second layer 118. For example, the source and drain electrodes 121 and 122 may each be formed of at least one material selected from the group of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) in a single- or multi-layered structure.

A protection layer 123 is formed on the source electrode 121 and the drain electrode 122 in order to prevent the source electrode 121 and the drain electrode 122 from being eroded by moisture and/or oxygen. In the present embodiment, the protection layer 123 is formed only on the source electrode 121 and the drain electrode 122. However, the protection layer 123 may also be formed on a wiring (not shown) formed on the same level as the source electrode 121 and the drain electrode 122. The protection layer 123 includes a metal oxide or a transparent conductive oxide.

An insulating layer 124 (i.e., a passivation layer and/or a planarization layer) is formed on the source and drain electrodes 121 and 122. The insulation layer 124 protects and planarizes a thin film transistor (TFT) located therebelow. The insulation layer 124 may have any of various forms and may be formed of an organic material, such as Benzocyclobutene (BCB) or Acryl, or an inorganic material such as SiNx. The insulation layer 124 may have a single- or multi-layered structure.

In the pixel region PXL, a first electrode 125, which is a pixel electrode including the transparent conductive material used to form the first layer 117, is formed on the gate insulation layer 116.

The first electrode 125 may serve as an anode from among electrodes included in an organic light-emitting diode (OLED) and may be formed of any of various conductive materials. The first electrode 125 may be formed as a transparent electrode or as a reflective electrode according to its purpose.

For example, when the first electrode 125 is formed as a transparent electrode, the first electrode 125 may be formed of an indium tin oxide (ITO), an indium zinc oxide (IZO), a zinc oxide (ZnO), or an indium oxide (In₂O₃). When the first electrode 125 is formed as a reflective electrode, the first electrode 125 may be formed by forming a reflective layer from silver (Ag), magnesium (Mg), aluminum (Al), platinum (Pt), palladium (Pd), gold (Au), nickel (Ni), neodymium (Nd), iridium (Jr), chromium (Cr) or a compound thereof and depositing ITO, IZO, ZnO, or In₂O₃ on the reflective layer.

A first insulation layer 126 is formed together with the interlayer insulation layer 119, around the first electrode 125. A first opening C1, via which the first electrode 125 is exposed, is formed in the first insulation layer 126. A second insulation layer 127 is formed on the first insulation layer 126. A second opening C2, via which the first electrode 125 is exposed, is formed in the second insulation layer 127.

An intermediate layer 128 is formed on the first electrode 125 within the second opening C2. The intermediate layer 128 may be formed by deposition.

In the embodiment of FIG. 3, the intermediate layer 128 is formed to correspond to only each sub-pixel, namely, the first electrode 125, which has been patterned. However, this is an example for convenience of explanation of the structure of a sub-pixel, and various other embodiments may be possible.

The intermediate layer 128 may be formed of a low-molecular weight organic material or a high-molecular weight organic material.

For example, the intermediate layer 128 includes an emissive layer. However, the intermediate layer 128 may further include at least one of a hole injection layer (HIL), a hole transport layer (HTL), an electron transport layer (ETL), and an electron injection layer (EIL). The present embodiment is not limited thereto, and the intermediate layer 128 may further include the other functional layers in addition to an organic emissive layer.

A second electrode 129 corresponding to a common electrode of an OLED is formed on the intermediate layer 128. The second electrode 129 may be formed as a transparent electrode or as a reflective electrode, similar to the first electrode 125.

When the second electrode 129 is formed as a transparent electrode, the second electrode 129 may be formed by depositing a metal having a low work function, such as lithium (Li), calcium (Ca), lithium fluoride/calcium (LiF/Ca), lithium fluoride/aluminum (LiF/Al), aluminum (Al), magnesium (Mg), or a compound thereof, on the intermediate layer 128 and then forming an auxiliary electrode thereon from a transparent electrode material, such as ITO, IZO, ZnO, In₂O₃, or the like.

When the second electrode layer 129 is formed as a reflective electrode, the second electrode 129 may be formed by depositing Li, Ca, LiF/Ca, LiF/Al, Al, Mg, or a compound thereof on the intermediate layer 128 so as to cover the entire surface of the substrate 110.

When the first electrode 125 is formed as a transparent electrode or as a reflective electrode, it may be formed in a shape corresponding to the opening in each sub-pixel. When the second electrode 129 is formed as a transparent electrode or a reflective electrode, it may be formed to cover the entire display area.

Alternatively, the second electrode 129 may be formed to have any of various patterns instead of being formed on the entire display area. The first electrode 125 and the second electrode 129 may be stacked in an order opposite to the order in which the first electrode 125 and the second electrode 129 are illustrated as being sequentially stacked in the embodiment of FIG. 3.

In the capacitor area CAP, a first electrode 130, a second electrode 131, and a portion of the gate insulation layer 116 between the first electrode 130 and the second electrode 131 are formed.

The first electrode 130 may be formed of the same material as used to form the source region 113 and the drain region 114 of the semiconductor active layer 112 of a TFT. In this embodiment, the first electrode 130 includes a semiconductor doped with ion impurities.

When the first electrode 130 is formed of an intrinsic semiconductor undoped with ion impurities, the capacitor formed has a metal oxide semiconductor (MOS) capacitor (CAP) structure. However, as in the embodiment of FIG. 3, when the first electrode 130 is formed of a semiconductor doped with ion impurities, the capacitor has a metal-insulator-metal (MIM) CAP structure and thus the electrostatic capacitance thereof can be maximized.

The portion of the gate insulation layer 116, which serves a dielectric layer, is formed on the first electrode 130. The second electrode 131 may be formed of the transparent conductive oxide used to form the first layer 117 and is formed on the portion of the gate insulation layer 116.

The non-display area NDA is formed outside the display area DA.

As described above, the non-display area NDA includes a region including a circuit pattern formed by patterning a wiring that is electrically connected to each element of the display area DA. A gate driver electrically connected to the gate electrodes 117 and 118, a data driver electrically connected to the source electrode 121 and the drain electrode 122, and the like are formed in the non-display area NDA. A circuit electrode 132 is also formed in the non-display area NDA. The circuit electrode 132 may be formed of the same material as used to form the source electrode 121 and the drain electrode 122.

The encapsulation portion 140 is formed on the substrate 110 and attached thereto. The encapsulation portion 140 protects the OLED and other thin films from external moisture, oxygen, or the like.

The encapsulation portion 140 may be a glass substrate having rigidity, a polymer resin substrate, or a flexible film. The encapsulation portion 140 may be formed by alternately stacking an organic layer and an inorganic layer over the OLED. In these embodiments, a plurality of organic layers and a plurality of inorganic layers are alternately stacked.

The sealing area SA partially overlaps the non-display area NDA. The sealing area SA includes the sealing portion 301 formed therein. The sealing portion 301 seals the region between the substrate 110 and the encapsulation portion 140. In some embodiments, the sealing portion 301 includes a glass frit.

A touch screen panel wiring 159 is formed on the encapsulation portion 140 and is electrically connected to the first and second electrode pattern portions 151 and 152 included in the touch screen panel 150 of FIG. 2.

The touch screen panel wiring 159 is located in the non-display area NDA of the display panel 160. In other words, the touch screen panel wiring 159 is formed on a portion of the outer surface of the encapsulation portion 140 that overlaps the non-display area NDA in a vertical direction.

In the display device 100, a laser radiation apparatus radiates laser light to the sealing portion 301 located between the substrate 110 and the encapsulation portion 140. The substrate 110 and the encapsulation portion 140 are firmly attached to each other due to melting of the sealing portion 301 from the laser radiation.

However, since the touch screen panel wiring 159 is located on the sealing portion 301, some of the laser beams are reflected by the touch screen panel wiring 159 and thus do not pass through the encapsulation portion 140. Thus, the temperature profile is distorted in an area overlapping the touch screen panel wiring 159. Accordingly, when the sealing portion 301 is observed after going through the laser radiation process, the strength of the sealing portion 301 is degraded.

To address this problem, the laser radiation apparatus may apply increased thermal energy to the sealing portion 301. However, the heat applied to the sealing portion 301 may destroy the circuit pattern formed below the sealing portion 301. In other words, when high energy is applied, the thermal temperature of the center of the sealing portion 301 applied with the laser beams rapidly increases and the number of pores in the sealing portion 301 and the sizes of these pores also increases. Accordingly, the circuit pattern may be damaged, and the strength of the sealing portion 301 may decrease. In some embodiments, the circuit pattern includes the circuit electrode 132.

According to at least one embodiment, the thermal conduction portion 302 is formed between the encapsulation portion 140 and the sealing portion 301, in order to increase the strength of the sealing portion 301 without applying high energy to the sealing portion 301.

The thermal conduction portion 302 contacts the sealing portion 301.

In more detail, a first surface 304 of the thermal conduction portion 302 contacts at least a portion of an upper surface of the sealing portion 301. The upper surface of the sealing portion 301 faces the encapsulation portion 140. A second surface 305 of the thermal conduction portion 302 that is opposite to the first surface 304 contacts one surface of the encapsulation portion 140. The surface of the encapsulation portion 140 is a surface that faces the sealing portion 301.

The thermal conduction portion 302 includes a highly-conductive material, for example, at least one material selected from among aluminum (Al), platinum (Pt), palladium (Pd), silver (Ag), magnesium (Mg), gold (Au), nickel (Ni), neodymium (Nd), iridium (Jr), chromium (Cr), calcium (Ca), molybdenum (Mo), titanium (Ti), tungsten (W), and copper (Cu). Alternatively, the material included in the thermal conduction portion 302 may be any material as long as it is a highly-conductive material.

The sealing portion 301 is formed in the sealing area SA, which partially overlaps the non-display area NDA surrounding the display area DA. The thermal conduction portion 302 is formed in accordance with the pattern of the sealing portion 301.

To facilitate the transmission of laser light via the area of the encapsulation portion 140 having no touch screen panel wiring 159 formed thereon, the thermal conduction portion 302 is formed to have a particular pattern. The thermal conduction portion 302 may be a pattern having a plurality of openings 308. Although the thermal conduction portion 302 is described as having a mesh-type pattern above, embodiments of the described technology are not limited thereto.

The thermal conduction buffer layer 303, which acts as a thermal buffer, may be further formed to reduce boiling of the thermal conduction portion 302 during transmission of heat from a maximum heat-generation portion of the sealing portion 301 to the thermal conduction portion 302.

The thermal conduction buffer layer 303 is formed between the encapsulation portion 140 and the thermal conduction portion 302. The thermal conduction buffer layer 303 at least partially overlaps the thermal conduction portion 302.

A first surface 306 of the thermal conduction buffer layer 303 at least partially contacts the thermal conduction portion 302. A second surface 307 of the thermal conduction buffer layer 303 that is opposite to the first surface 306 contacts the encapsulation portion 140.

The thermal conduction buffer layer 303 is formed of an inorganic material in order to buffer direct heat-conduction between the sealing portion 301 and the thermal conduction portion 302. For example, the thermal conduction buffer layer 303 includes a silicon oxide, a silicon nitride, or the like.

The thermal conduction buffer layer 303 may be formed to be relatively thin so as not to interfere with the transmission of laser light. According to an experimental example of the described technology, when the thermal conduction buffer layer 303 had a thickness of about 1000 Å, the thermal conduction buffer layer 303 had transmissivity of about 90%. However, the effects of the described technology are not limited by the above disclosed parameters used in the experimental example and it is expected that substantially the same or similar benefits are obtained from other parameters that those described in the above experimental example.

In some embodiments, in the display device 100 having the above-described structure, the sealing portion 301 is formed in the sealing area SA. The sealing portion 301 extends along the encapsulation portion 140 in a horizontal direction from where the touch screen panel wiring 159 is located to a location where no touch screen panel wiring 159 is located.

The laser light emitted from the laser radiation apparatus are radiated to the sealing portion 301 via the encapsulation portion 140 where no touch screen panel wiring 159 is located. The laser light is reflected from the touch screen panel wiring 159 on the encapsulation portion 140.

When thermal energy generated by the light radiated from the laser radiation apparatus in the sealing portion 301, heat from the maximum heat-generation portion, or a location of maximum heat generation, of the sealing portion 301 is transmitted to the thermal conduction portion 302.

Due to the transmission of the heat from the maximum heat-generation portion of the sealing portion 301 to the thermal conduction portion 302, the glass fit included in a portion of the sealing portion 301 to which no laser light is transmitted due to the presence of the touch screen panel wiring 159 is also melted. Thus, the substrate 110 and the encapsulation portion 140 are bonded to each other.

Since the thermal conduction portion 302 is overlapped by a portion of the thermal conduction buffer layer 303, the thermal conduction portion 302 can be prevented from boiling due to the heat from the maximum heat-generation portion of the sealing portion 301.

According to an experimental example of the described technology, driving failures in the non-display area having the circuit pattern were prevented even when the temperature of the thermal conduction portion 302 reached about 300° C. or greater. Thus, the sealing portion 301 can be effectively fused because of the heat conductivity of the thermal conduction portion 302.

In addition, since heat was efficiently conducted via the thermal conduction portion 302, dead space of the display device 100 such as the non-display area NDA can be reduced and thus the display device 100 may be formed with a thinner profile.

As described above, a display device according to at least one embodiment can ensure structural strength by substantially uniformly radiating laser light onto a sealing portion included therein. Thus, the sealing portion may have improved reliability.

Moreover, since heat energy does not need to be increased during melting a sealant, the circuit pattern layer of the display panel can be prevented from being damaged.

It should be understood that the exemplary embodiments described herein should be considered in a descriptive sense only and not for purposes of limitation. Descriptions of features or aspects within each embodiment should typically be considered as available for other similar features or aspects in other embodiments.

While the described technology has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A display device, comprising:
a base substrate including a display area and a non-display area surrounding the display area;
a display unit formed in the display area;
an encapsulation substrate formed over the base substrate;
a touch screen panel formed over the encapsulation substrate;
a sealant film interposed between the base substrate and the encapsulation substrate; and
a thermal conductor interposed between the sealant film and the encapsulation substrate.

2. The display device of claim 1, wherein the touch screen panel includes a wiring formed over the encapsulation substrate and facing the non-display area, and wherein the sealant film extends along the encapsulation substrate from a position overlapping the wiring to a position not overlapping the wiring.

3. The display device of claim 2, wherein the thermal conductor is configured to receive thermal energy via the sealant film.

4. The display device of claim 2, further comprising a circuit pattern formed in the non-display area.

5. The display device of claim 2, wherein the thermal conductor contacts the sealant film.

6. The display device of claim 5, wherein the thermal conductor has first and second surfaces opposing each other, wherein the first surface of the thermal conductor contacts at least a portion of an upper surface of the sealant film, and wherein the second surface of the thermal conductor contacts the encapsulation substrate.

7. The display device of claim 5, wherein the sealant film surrounds the display area and at least partially overlaps the non-display area and wherein the thermal conductor surrounds the display area and overlaps the sealant film.

8. The display device of claim 7, wherein the thermal conductor defines a pattern having a plurality of openings.

9. The display device of claim 8, wherein the thermal conductor defines a mesh-type pattern.

10. The display device of claim 1, wherein the thermal conductor is formed at least partially of metal.

11. The display device of claim 5, further comprising a thermal conduction buffer layer interposed between the encapsulation substrate and the thermal conductor.

12. The display device of claim 11, wherein the thermal conduction buffer layer at least partially overlaps the thermal conductor.

13. The display device of claim 11, wherein the thermal conduction buffer layer has first and second surfaces opposing each other, wherein the first surface of the thermal conductor buffer layer contacts the thermal conductor, and wherein the second surface of the thermal conduction buffer layer contacts the encapsulation substrate.

14. The display device of claim 11, wherein the thermal conduction buffer layer is formed at least partially of an inorganic material.

15. The display device of claim 11, wherein the thickness of the thermal conduction buffer layer is less than that of the thermal conductor.

16. The display device of claim 1, wherein the touch screen panel is integrally formed on the encapsulation substrate, and wherein the touch screen panel is an electrostatic capacitive type touch screen panel, a resistive type touch screen panel, an electro-magnetic type touch screen panel, a saw type touch screen panel, or an infrared type touch screen panel.

17. The display device of claim 16, wherein the touch screen panel comprises:
a plurality of electrode patterns formed on the encapsulation portion; and
at least one insulation layer electrically insulating the electrode patterns from each other.

18. The display device of claim 17, wherein the electrode patterns comprise a plurality of first electrode patterns and a plurality of second electrode patterns, wherein the first electrode patterns are arranged in a first direction and are spaced apart from each other, and wherein the second electrode patterns are arranged in a second direction that intersects the first direction and are spaced apart from each other.

19. The display device of claim 1, wherein the display unit comprises:
a thin film transistor; and
an organic light-emitting diode (OLED) electrically connected to the thin film transistor and comprising an intermediate layer, wherein the intermediate layer includes a first electrode, a second electrode, and an emission layer interposed between the first and second electrodes.

20. The display device of claim 1, wherein the sealant film comprises a glass frit.
